(19) United States
(12) Patent Application Publication
(10) Pub. No.: US 2011/0005817 A1
(43) Pub. Date: Jan. 13, 2011

(54) CAPACITOR-FORMING MATERIAL AND PRINTED WIRING BOARD PROVIDED WITH CAPACITOR

(75) Inventors: Ayumi Ito, Saitama (JP); Akihiro Kanno, Saitama (JP); Naohiko Abe, Saitama (JP); Akiko Sugioka, Saitama (JP)

Correspondence Address: GREENBLUM & BERNSTEIN, P.L.C., 1950 ROLAND CLARKE PLACE, RESTON, VA, 20191, US

(73) Assignee: MITSUI MINING & SMELTING CO., LTD., Tokyo (JP)

(21) Appl. No.: 12/933,261

(22) PCT Filed: Feb. 4, 2009
(86) PCT No.: PCT/JP2009/051905

§ 371 Date: Sep. 17, 2010

(30) Foreign Application Priority Data
Mar. 31, 2008 (JP) 2008-093057

(51) Int. Cl. H05K 1/09; H01G 4/30; H01R 43/00

(52) U.S. Cl. 174/257; 361/301.4; 29/825

(57) ABSTRACT

An object of the present invention is to provide a capacitor-forming material having a stable adhesion between a dielectric layer and an electrode-forming layer. To achieve the object, the capacitor-forming material in which an oxides dielectric layer is provided between a top-electrode-forming layer and a bottom-electrode-forming layer, wherein at least one of the top-electrode-forming layer and the bottom-electrode-forming layer has a two-layer construction constituted with a bulk-metal layer and a composite layer composed of metal and metal oxide which is made to contact with the oxides dielectric layer. In particular, it is preferable to employ a capacitor-forming material having the top-electrode-forming layer which has two-layer construction constituted with the bulk-metal layer and the composite layer composed of metal and metal oxide, and has a layer construction in which the bulk-metal layer and the composite layer composed of metal and metal oxide are stacked to make the composite layer composed of metal and metal oxide contact with the oxides dielectric layer.

### TECHNICAL FIELD

The present invention relates to a capacitor-forming material and a printed wiring board provided with a capacitor.

### BACKGROUND ART

The capacitor-forming material disclosed in the present invention has a structure having a dielectric layer provided between a top-electrode-forming layer and a bottom-electrode-forming layer. The top-electrode-forming layer and the bottom-electrode-forming layer are formed by an etching process or the like to finish a capacitor circuit. Such a capacitor-forming material is generally used as a material for forming a capacitor in a printed wiring board, as is disclosed in Patent document 1, for example.

However, a capacitor-forming material constituting [top-electrode-forming layer]/[dielectric layer]/[bottom-electrode-forming layer] construction sometime causes a problem in adhesion at the interface between the bottom-electrode-forming layer and the dielectric layer, and at the interface between the top-electrode-forming layer and the dielectric layer. When the adhesion in these positions is poor, a space is formed between the dielectric layer and the electrode-forming layers, and the formed capacitor circuit does not satisfy the quality required as the capacitor.

For this reason, to solve such a problem, Patent document 2 discloses “in a thin film capacitor provided on a substrate which has a pair of electrode films and a dielectric film provided between the pair of the electrode films, the thin film capacitor which is characterized in that at least one of the pair of the electrode films is a Cu electrode film containing Cu, an adhesion film containing Cu₂O is provided between the Cu electrode film and the dielectric film, and the dielectric film is an oxide dielectric film” of which object is to prove a thin film capacitor or the like, which can sufficiently prevent separation between the electrode film and the dielectric film while sufficiently securing the electroconductivity of an electrode film, even when inexpensive Cu is used as an electrode.

In the Patent document 2, the method disclosed in the column 0034 for forming of a dielectric film is that “A dielectric film 4 may be formed by employing film-formation technologies, a solution-coating with baking method such as a sol-gel process and an MOD method (organometallic compound deposition method), a PVD method such as a sputtering method and a CVD method and the like.”, i.e. the sol-gel process is suggested. However, in examples of Patent document 2, the method for forming of a dielectric film disclosed is just a sputtering method using a BST target as is described in column 0048.

[Patent document 1] WO 2006/118236

[Patent document 2] Japanese Patent Application Laid-Open No. 2007-329189

### DISCLOSURE OF THE INVENTION

### Problems to be Solved by the Invention

However, in the invention disclosed in Patent document 2, a sol-gel process employed for forming the dielectric layer has a drawback that the adhesion between the dielectric layer and the electrode layer is not enough. Specifically, the adhesion between the electrode-forming layer and the oxides dielectric layer cannot achieve a practical level (0.3 kgf/cm or more).

From the above circumstances, a capacitor-forming material for use in manufacturing of a printed wiring board having an excellent adhesion between the top-electrode-forming layer and the oxides dielectric layer and has a high capacitance even when the oxides dielectric layer is formed by using the sol-gel process and a printed wiring board provided with the capacitor have been required.

### Means for Solving the Problems

Then, as a result of extensive investigations, the present inventors conceived that the present invention described below enables to provide a capacitor-forming material for use in manufacturing of a printed wiring board in which adhesion between the electrode-forming layer and the dielectric layer is stabilized and has the high capacitance, and a printed wiring board provided with a capacitor. The outline of the present invention will be described below.

Capacitor-forming material: A capacitor-forming material according to the present invention is a capacitor-forming material provided with an oxides dielectric layer between a top-electrode-forming layer and a bottom-electrode-forming layer, wherein at least one of the top-electrode-forming layer and the bottom-electrode-forming layer has a two-layer construction constituted with a bulk-metal layer and a composite layer composed of metal and metal oxide which is made to contact with the oxides dielectric layer. The capacitor-forming material is also a capacitor-forming material characterized in three-layer construction in which a different-kind-metal layer is provided between the bulk-metal layer and the composite layer composed of metal and metal oxide. So, the capacitor-forming material has three types of layer constructions which will be described later. These will be referred to as Type-I (Type-Ia and Type-Ib), Type-II (Type-IIa and Type-IIb) and Type-III (Type-IIIa and Type-IIIb), according to the type.

Method for manufacturing capacitor-forming material: The method employed for manufacturing the capacitor-forming material according to the present invention is preferable to be selected from three manufacturing methods which will be described below according to the type of the capacitor-forming material.

In the method for manufacturing the capacitor-forming material of Type-I according to the present invention, stacked body is manufactured by the process characterized in that the oxides dielectric layer is formed on a surface of the bottom-electrode-forming layer; and then the top-electrode-forming layer having the two-layer construction constituting [bulk-metal layer]/[composite layer composed of metal and metal oxide], or the top-electrode-forming layer having a three-layer construction constituting [bulk-metal layer]/[different-kind-metal layer]/[composite layer composed of metal and metal oxide] is formed on the surface of the oxides dielectric layer. The stacked body provided in the manufacturing method for Type-I has a layer construction of (“top-electrode-forming layer ([composite layer composed of metal and metal oxide]/[bulk-metal layer])/dielectric layer/bottom-electrode-forming layer”, or “top-electrode-forming layer ([composite layer composed of metal and metal oxide]/[different-kind-metal layer]/[bulk-metal layer])/dielectric layer/bottom-electrode-forming layer”). In addition, the bottom-electrode-forming layer of Type-I is a layer consisting of a metal, in which a metal oxide is not intentionally contained.

In the method for manufacturing the capacitor-forming material of Type-II according to the present invention, stacked body is manufactured by the process characterized in that the bottom-electrode-forming layer having two-layer construction is formed by providing a composite layer composed of metal and metal oxide on a surface of the bulk-metal layer, or the bottom-electrode-forming layer having three-layer construction is formed by providing a different-kind-metal layer on a surface of a bulk-metal layer followed by providing a composite layer composed of metal and metal oxide on a surface of the different-kind-metal layer, then the oxides dielectric layer is formed on the composite layer composed of metal and metal oxide provided on the surface of the bottom-electrode-forming layer, and further the top-electrode-forming layer is formed on the surface of the oxides dielectric layer. The stacked body provided in the manufacturing method for Type-II has a layer construction constituted with (“top-electrode-forming layer/dielectric layer/bottom-electrode-forming layer ([composite layer composed of metal and metal oxide]/[bulk-metal layer])”, or “top-electrode-forming layer/dielectric layer/bottom-electrode-forming layer ([composite layer composed of metal and metal oxide]/[different-kind-metal layer]/[bulk-metal layer])”). In addition, the top-electrode-forming layer of Type-II is a layer consisting of a metal, in which a metal oxide is not intentionally contained.

In the method for manufacturing the capacitor-forming material of Type-III according to the present invention, stacked body is manufactured by the process characterized in that the bottom-electrode-forming layer having a two-layer construction obtained by providing a composite layer composed of metal and metal oxide on a surface of a bulk-metal layer, or the bottom-electrode-forming layer having a three-layer construction obtained by providing a different-kind-metal layer on the surface of a bulk-metal layer followed by providing a composite layer composed of metal and metal oxide on a surface of the different-kind-metal layer is formed, then the oxides dielectric layer is formed on the composite layer composed of metal and metal oxide provided on the surface of the bottom-electrode-forming layer, and further the top-electrode-forming layer having a two-layer construction constituting [bulk-metal layer]/[composite layer composed of metal and metal oxide], or the top-electrode-forming layer having a three-layer construction constituting [bulk-metal layer]/[different-kind-metal layer]/[composite layer composed of metal and metal oxide] is provided on the surface of the oxides dielectric layer.

Printed wiring board according to the present invention: The printed wiring board according to the present invention is provided with an embedded capacitor layer, and is obtained by forming the embedded capacitor layer by using the above described capacitor-forming material.

The printed wiring board according to the present invention is also obtained by providing the above described capacitor-forming material in a printed wiring board.

### ADVANTAGE OF THE INVENTION

A capacitor-forming material according to the present invention is the capacitor-forming material provided with an oxides dielectric layer between a top-electrode-forming layer and a bottom-electrode-forming layer, wherein at least one of the top-electrode-forming layer and the bottom-electrode-forming layer has “a two-layer construction constituting [bulk-metal layer]/[composite layer composed of metal and metal oxide]”, or “a three-layer construction constituting [bulk-metal layer]/[different-kind-metal layer]/[composite layer composed of metal and metal oxide]”. By employing such a structure, the capacitor-forming material shows an enough adhesion between the oxides dielectric layer and each of the electrode-forming layers. As a result, the quality of the capacitor can be significantly stabilized. Therefore, the printed wiring board in which the capacitor layer is formed by using the capacitor-forming material for use in manufacturing of the printed wiring board is made to have the capacitor showing a stable capacitor performance, and is made to be a multilayer printed wiring board of high quality.

### BRIEF DESCRIPTION OF THE DRAWINGS

FIG. 1 is a schematic sectional view showing a layer construction of a capacitor-forming material (Type-Ia) according to the present invention;

FIG. 2 is a schematic sectional view showing a layer construction of a capacitor-forming material (Type-Ib) which is provided with a different-kind-metal layer, according to the present invention;

FIG. 3 is a schematic sectional view showing a layer construction of a capacitor-forming material (Type-IIa) according to the present invention;

FIG. 4 is a schematic sectional view showing a layer construction of a capacitor-forming material (Type-IIb) which is provided with a different-kind-metal layer, according to the present invention;

FIG. 5 is a schematic sectional view showing a layer construction of a capacitor-forming material (Type-IIIa) according to the present invention;

FIG. 6 is a schematic sectional view showing a layer construction of a capacitor-forming material (Type-IIIb) which is provided with a different-kind-metal layer, according to the present invention;

FIG. 7 is a spectrum on one example showing a state in which “nickel spectrum” and “nickel oxide spectrum” that can be detected independently in an XPS measurement; and

FIG. 8 is a schematic view showing a measurement point in an XPS measurement and an XRD measurement.

### BEST MODE FOR CARRYING OUT THE INVENTION

Constructions of capacitor-forming materials for use in manufacturing of a printed wiring board and the printed wiring board provided with a capacitor according to the present invention will be described below.

### [Embodiment of Capacitor-Forming Material for Use in Manufacturing Printed Wiring Board]

The capacitor-forming material 1 for use in manufacturing of the printed wiring board according to the present invention has an oxides dielectric layer 4 provided between the top-electrode-forming layer 2 and the bottom-electrode-forming layer 3, wherein at least one of the top-electrode-forming layer 2 and the bottom-electrode-forming layer 3 has a two-layer construction constituted with a composite layer 6 composed of metal and metal oxide which is made to contact with a bulk-metal layer 5/the oxides dielectric layer. So, the capacitor-forming material can comprise three types of layer constructions. Each of the capacitor-forming materials of Type-I to Type-III will be described below with reference to the drawings. Each type includes a type-a without a different-kind-metal layer and a type-b with the different-kind-metal layer. Therefore, the types are classified in such a manner as Type-Ia and Type-Ib.

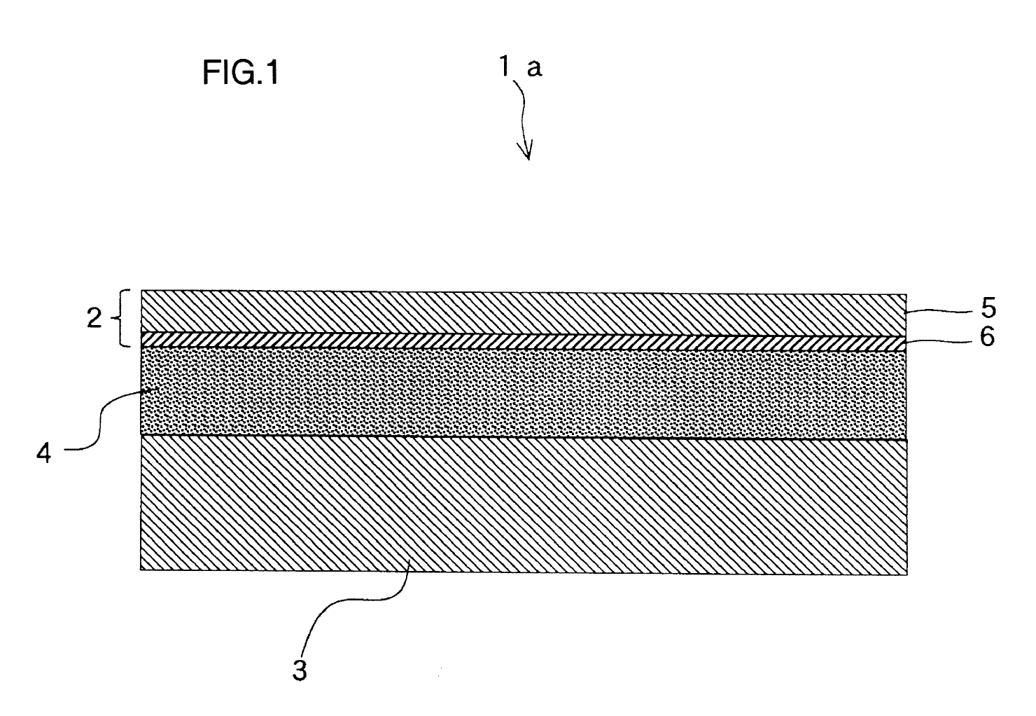

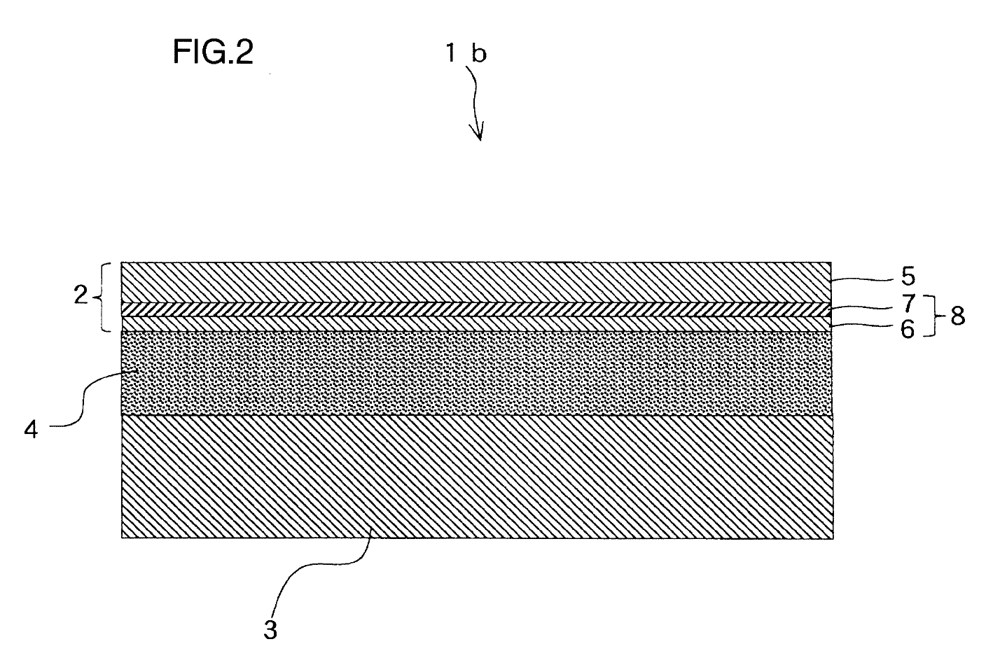

The capacitor-forming material Type-I includes Type-Ia illustrated in FIG. 1 and Type-Ib illustrated in FIG. 2. As is obvious in FIG. 1, a capacitor-forming material 1a (Type-Ia) for use in manufacturing of the printed wiring board according to the present invention is characterized in having the top-electrode-forming layer 2 composed of two layers constituted with the bulk-metal layer 5 and the composite layer 6 composed of metal and metal oxide. A capacitor-forming material 1b (Type-Ib) for use in manufacturing of the printed wiring board according to the present invention illustrated in FIG. 2 has the top-electrode-forming layer 2 composed of three layers constituted with the bulk-metal layer 5, the different-kind-metal layer 7 and the composite layer 6 composed of metal and metal oxide.

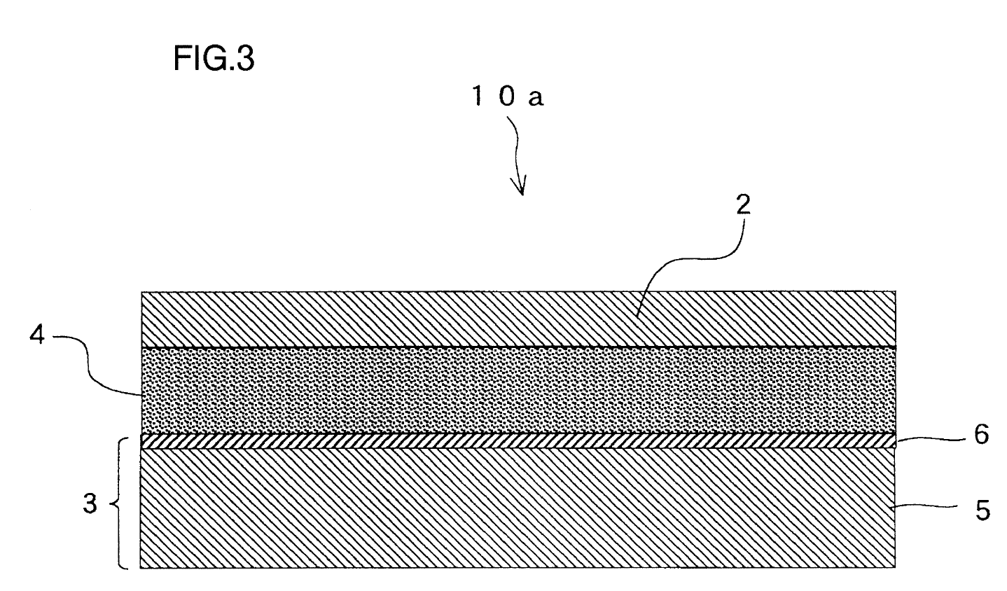

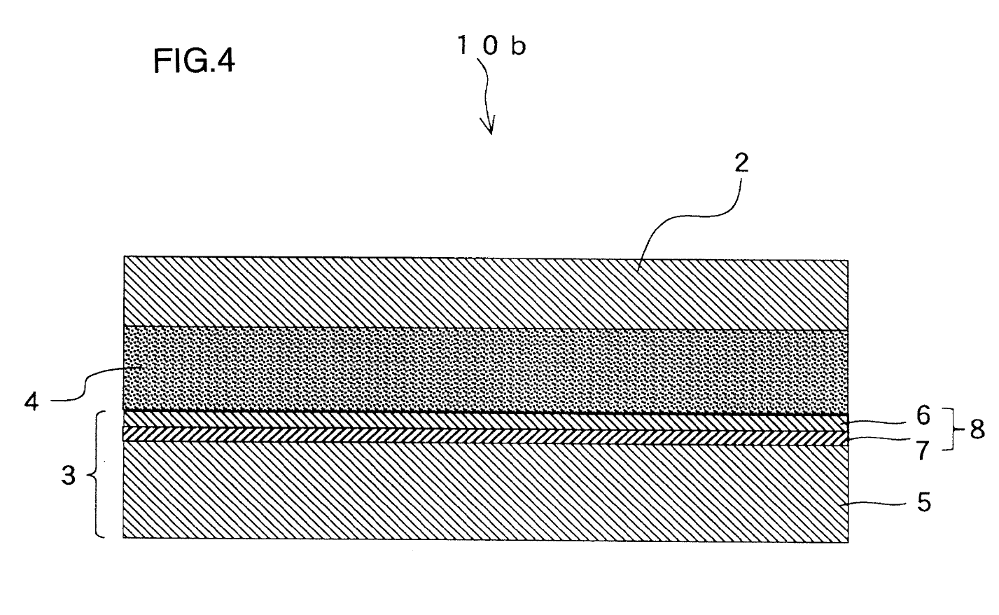

The capacitor-forming material Type-II includes Type-IIa illustrated in FIG. 3 and Type-IIb illustrated in FIG. 4. As is obvious in FIG. 3, a capacitor-forming material 10a (Type-IIa) for use in manufacturing of the printed wiring board according to the present invention is characterized in having the bottom-electrode-forming layer 3 composed of two layers constituted with the bulk-metal layer 5 and the composite layer 6 composed of metal and metal oxide. A capacitor-forming material 10b (Type-IIb) for use in manufacturing of the printed wiring board according to the present invention illustrated in FIG. 4 has the bottom-electrode-forming layer 3 composed of three layers constituted with the bulk-metal layer 5, the different-kind-metal layer 7 and the composite layer 6 composed of metal and metal oxide.

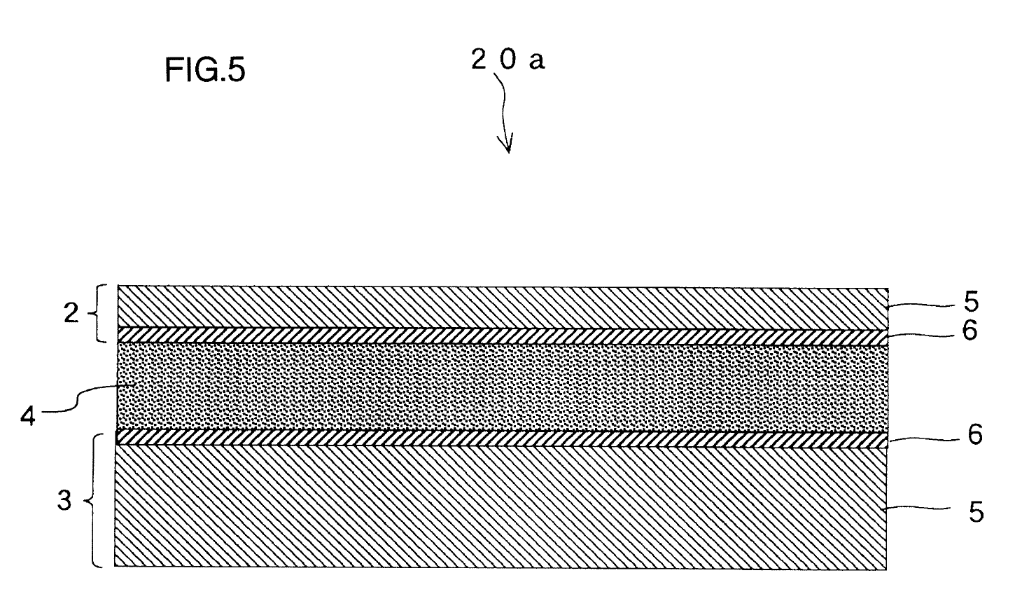

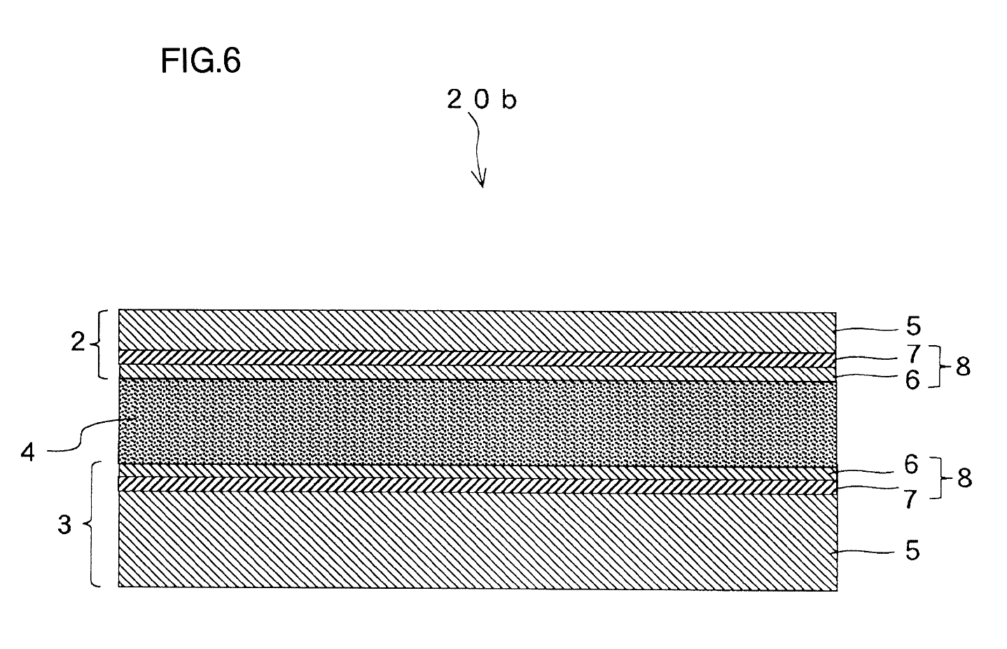

The capacitor-forming material of Type-III includes Type-IIIa illustrated in FIG. 5 and Type-IIIb illustrated in FIG. 6. As is obvious in FIG. 5, a capacitor-forming material 20a (Type-IIIa) for use in manufacturing of the printed wiring board according to the present invention is characterized in having the top-electrode-forming layer 2 composed of two layers constituted with the bulk-metal layer 5 and the composite layer 6 composed of metal and metal oxide, and having the bottom-electrode-forming layer 3 also composed of two layers constituted with the bulk-metal layer 5 and the composite layer 6 composed of metal and metal oxide. A capacitor-forming material 20b (Type-IIIb) for use in manufacturing of the printed wiring board according to the present invention illustrated in FIG. 6 has the top-electrode-forming layer 2 composed of three layers constituted with the bulk-metal layer 5, the different-kind-metal layer 7 and the composite layer 6 composed of metal and metal oxide, and has the bottom-electrode-forming layer 3 also composed of three layers constituted with the bulk-metal layer 5, the different-kind-metal layer 7 and the composite layer 6 composed of metal and metal oxide.

Each of the capacitor-forming materials Type-I to Type-III to which the layer constructions are described are common in a layer construction constituted with the oxides dielectric layer 4 provided between the top-electrode-forming layer 2 and the bottom-electrode-forming layer 3, and a bulk metal of at least one of the top-electrode-forming layer 2 and the bottom-electrode-forming layer 3 is provided with “composite layer 6 composed of metal and metal oxide” at an interface side made to contact with the oxides dielectric layer 4. Because the composite layer 6 composed of metal and metal oxide is provided, the adhesion between any of the electrode-forming layers and the oxides dielectric layer 4 is enhanced. However, because poor adhesion with the oxides dielectric layer 4 tends to occur between “top-electrode-forming layer 2” and “oxides dielectric layer 4”, it is effective to provide “composite layer 6 composed of metal and metal oxide” in the top-electrode-forming layer. Incidentally, the different-kind-metal layer is provided in both of the top-electrode-forming layer 2 and the bottom-electrode-forming layer 3 in Type-IIIb, but it shall be clearly stated that Type-IIIb can have a construction in which the different-kind-metal layer is provided in either one of the top-electrode-forming layer 2 and the bottom-electrode-forming layer 3.

By using the above described capacitor-forming material according to the present invention, a capacitor circuit embedded in the printed wiring board can be formed by processing laminate with a pre-preg or the like followed by etching at least one of the top-electrode-forming layer 2 and the bottom-electrode-forming layer 3. The capacitor-forming material according to the present invention can be embedded in the printed wiring board after forming a circuit by an etching process. In any case, the capacitor-forming material according to the present invention is made to function as a capacitor in the printed wiring board. The present invention will be described in more detail below with typical examples Type-Ia illustrated in FIG. 1 and Type-Ib illustrated in FIG. 2. But it shall be clearly stated that each concept of “bulk-metal layer”, “different-kind-metal layer” and “composite layer composed of metal and metal oxide” described are common in the cases of Type-II and Type-III, in which the top-electrode-forming layer and the bottom-electrode-forming layer have a two-layer construction constituted with “[bulk-metal layer]/[composite layer composed of metal and metal oxide]” or a three-layer construction constituting “[bulk-metal layer]/[different-kind-metal layer]/[composite layer composed of metal and metal oxide]”.

Embodiment of Type-Ia: The construction will be described below with reference to FIG. 1. The capacitor-forming material 1 for use in manufacturing of the printed wiring board according to the present invention has the top-electrode-forming layer 2 constituted with the bulk-metal layer 5 and the composite layer 6 composed of metal and metal oxide in a stacked manner. The composite layer 6 composed of metal and metal oxide is made to contact with the oxides dielectric layer 4.

First, the composite layer 6 composed of metal and metal oxide will be described below. The composite layer composed of metal and metal oxide is preferable to be constituted including any one of a copper oxide, a nickel oxide, a copper alloy oxide and a nickel alloy oxide. This is because the composite layer composed of metal and metal oxide is superior in adhesion with both the oxides dielectric layer and the bulk-metal layer. The composite layer composed of metal and metal oxide is not composed of 100 wt % metal oxide, but contains a metal component not oxidized.

A copper oxide is mainly Cu₂O, but a concept described includes a composite of Cu₂O and CuO. In addition, the copper alloy oxide includes oxides and the like of a copper-phosphorous alloy, a copper-zinc alloy, a copper-nickel-zinc alloy, a copper-palladium alloy, a copper-gold alloy and a copper-silver alloy. The nickel oxide is mainly NiO. The nickel alloy oxide includes oxides of a nickel-phosphorus alloy, a nickel-cobalt alloy, a nickel-copper alloy, a nickel-palladium alloy, a nickel-silver alloy and a nickel-cobalt-palladium alloy. To specify a state of the composite layer composed of metal and metal oxide, two indexes described below can be used.

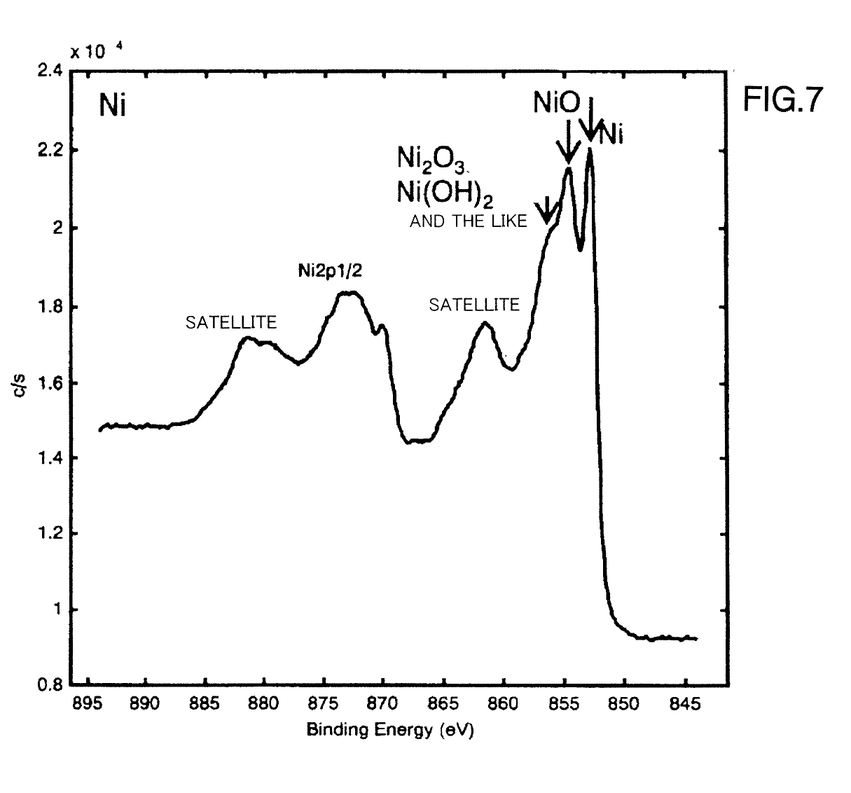

One index is obtained by an X-ray photoelectron spectroscopy analysis (XPS: X-ray Photoelectron Spectroscopy) on the composite layer composed of metal and metal oxide. In other words, when the composite layer composed of metal and metal oxide is analyzed with the XPS, it is preferable that spectra of the metal and the metal oxide constituting the composite layer composed of metal and metal oxide can be detected independently. As is illustrated in FIG. 7, the state corresponds to the state in which the peak of “nickel spectrum” and “nickel oxide spectrum” can be detected independently. When such a result is obtained in the XPS measurement, it is easy to obtain an effect for enhancing the adhesion between the oxides dielectric layer and the top-electrode-forming layer. Further when the capacitor-forming material has been subjected to annealing treatment which will be described below, the outermost surface of the composite layer composed of metal and metal oxide that is made to contact with the oxides dielectric layer may be oxidized not to make the composite layer composed of metal and metal oxide to be detected as a composite layer. So, it is preferable to expose the inner portion of the composite layer composed of metal and metal oxide to be exposed with a back sputtering technique or the like to investigate the exposed surface with the XPS.

In addition, investigation with an X-ray diffraction method (XRD) can be an index of the composite layer composed of metal and metal oxide as well. When the composite layer composed of metal and metal oxide is estimated to be a nickel-nickel oxide, a peak intensity ratio ([Ni (101)]/[NiO (200)]) calculated from the peak intensity of the (101) face of nickel (hereinafter referred to just “Ni (101)”) and the peak intensity of the (200) face of nickel oxide (hereinafter referred to just “NiO (200)”) is preferable to be in a range of 0.02 to 50, and is further preferable to be in a range of 0.05 to 10. The value of [Ni (101)]/[NiO (200)] is referred to as “peak intensity ratio”. In the present invention, the composite layer composed of metal and metal oxide will be investigated in a plurality of times (at least three times) with the X-ray diffraction method, and the index is preferable to be judged that the average value of the peak intensity ratio among investigations is in the above described range or not. When the peak intensity ratio is less than 0.02, the adhesion between the composite layer composed of metal and metal oxide and the oxides dielectric layer tends to deviate. So, it is not preferable. On the other hand, when the peak intensity ratio exceeds 50, the oxide content is too small to make adhesion between the composite layer composed of metal and metal oxide and the oxides dielectric layer hard to be achieved. When the peak intensity ratio is outside the range of 0.02 to 100, it may be considered that just metal or metal oxide substantially exists in the composite layer composed of metal and metal oxide. The peak intensity corresponds to an area (integrated intensity) obtained by integrating the intensity of the X-ray diffraction chart. Ni refers to PDF card #04-0850, and NiO refers to PDF card #44-1159.

The surface of the composite layer composed of metal and metal oxide is not rough but flat to provide an adequate adhesion between the composite layer composed of metal and metal oxide and the bulk-metal layer. As the proof, Table 1 shows comparison of the surface roughness (Ra) of the oxides dielectric layer composed of (Ba₁₋ₓSrₓ)TiO₃ (0≦x≦1) (referred to just “BST” in Table 1) formed on a nickel foil and the surface roughness (Ra) of the composite layer composed of metal and metal oxide (composite layer of nickel and nickel oxide) when the composite layer composed of metal and metal oxide having the average thickness of approximately 100 nm was provided on the surface of the oxides dielectric layer. The surface roughness (Ra) is a value measured in a visual field of 2 μm×2 μm according to JIS B 0601 by using an AFM. The result on each sample is obtained by investigating the surface roughness at different three positions in the same sample.

TABLE 1

| Layer construction | Ra (2 μm × 2 μm) |
|---|---|
| BST layer/Ni foil* | 1.76 nm-2.56 nm |
| NiO** layer/BST layer/Ni foil* | 4.40 nm-6.45 nm |

*Ni foil: bottom-electrode-forming layer (Nickel foil with the thickness of 50 μm)
**NiO layer: composite layer composed of metal and metal oxide (Nickel and Nickel oxide)

An average thickness of the composite layer composed of metal and metal oxide is preferable to be 5 nm or more. When the average thickness of the composite layer composed of metal and metal oxide is less than 5 nm, the adhesion between the oxides dielectric layer and the bulk-metal layer (and the different-kind-metal layer which will be described below) is not made stable. So, it is not preferable. In addition, from the viewpoint to secure uniformity of the average thickness of the composite layer composed of metal and metal oxide, the average thickness of the composite layer composed of metal and metal oxide is further preferable to be 10 nm or more. On the other hand, even when the average thickness of the composite layer composed of metal and metal oxide exceed 200 nm, the adhesion may not be improved so far. So, it can be estimated that the upper limit of the average thickness is 200 nm from the viewpoint of the manufacturing cost.

The above described composite layer composed of metal and metal oxide can be also formed by oxidization of the metal layer after forming on the oxides dielectric layer. However, in the present invention, it is preferable to form the composite layer composed of metal and metal oxide by using a sol-gel process, a sputtering method which is a dry process, or a physical vapor deposition method such as an EB vapor deposition method, because the methods can assure uniform thickness and composition of film.

Next, a bulk-metal layer constituting the top-electrode-forming layer will be described below. In the capacitor-forming material for use in manufacturing of the printed wiring board according to the present invention, the above described bulk-metal layer constituting the top-electrode-forming layer is preferable to be composed of any one of copper, nickel, a copper alloy and a nickel alloy. When the heat spreading is a priority for the top-electrode-forming layer, copper or a copper alloy is used. When the mechanical strength is a priority for the top-electrode-forming layer, nickel or a nickel alloy is preferable to be used.

The average thickness of above described bulk-metal layer constituting the top-electrode-forming layer is preferable to be 1 μm to 100 μm. When the average thickness of the bulk-metal layer is less than 1 μm, the mechanical strength is poor to be not preferable because a careful handling is required and deformation may be caused by a pressing pressure in the pressing process for multilayering a printed wiring board. On the other hand, when the average thickness of the bulk-metal layer exceed 100 μm, trimming of the shape for the top electrode is made hard by an etching method and result poor shape in the top electrode circuit formed. So, it is not preferable. The bulk-metal layer constituting the top-electrode-forming layer can be provided by laminating a metal foil, forming the bulk-metal layer with a plating method, a sputtering method or the like on the composite layer composed of metal and metal oxide (or a different-kind-metal layer when the different-kind-metal layer that will be described below is provided).

When the bottom-electrode-forming layer in the capacitor-forming material for use in manufacturing of the printed wiring board according to the present invention is constituted with a single metal component, it is preferable to use any one of copper, nickel, a copper alloy and a nickel alloy. The metal which can be used for the bottom-electrode-forming layer is a metal foil on which the oxides dielectric layer can be formed directly on the surface of the foil. So, the foil which can be used as the bottom-electrode-forming layer in the present invention includes all foils manufactured by a rolling method, an electrolytic method and the like. The foil includes a composite foil which has any one of layers of copper, the copper alloy, nickel and the nickel alloy provided on the top surface of the metal foil. For example, the foil material constituting the bottom-electrode-forming layer can also employ a composite foil having the nickel layer or the nickel alloy layer provided on the surface of the copper foil, and a composite foil having a zinc layer or a copper-zinc alloy layer provided on the surface of the copper foil.

When a fine capacitor circuit should be obtained by making forming ability of a capacitor circuit obtained by etching the bottom-electrode-forming layer excellent, the bottom-electrode-forming layer is preferable to be constituted with the copper or the copper alloy (brass composition, corson alloy composition and the like). This is because that the copper or the copper alloy is a material which enables etching fine. On the other hand, when excellent heat resistance of the bottom-electrode-forming layer of the capacitor is the priority to precede the improvement of heat resistance with respect to the heat history in the manufacturing process by using the sol-gel process, the bottom-electrode-forming layer is preferable to be constituted with the nickel or the nickel alloy (nickel-phosphorus alloy composition, nickel-cobalt alloy composition or the like). When the nickel-phosphorus alloy is employed, the phosphorus content in the alloy is preferable to be in a range of 0.1 wt % to 11 wt %, and further preferable to be in a range of 0.2 wt % to 3 wt %. When the phosphorus content is less than 0.1 wt %, the bottom-electrode-forming layer using the nickel-phosphorus alloy is not different from that using pure nickel eventually, i.e. the meaning of alloying is lost. On the other hand, when the phosphorus content exceeds 11 wt %, the phosphorus is segregated in the interface between the bottom-electrode-forming layer and the oxides dielectric layer, and the adhesion between the bottom-electrode-forming layer and the oxides dielectric layer is made poor, which results the bottom-electrode-forming layer easily peeling off from the oxides dielectric layer. The phosphorus content in the present invention is a value in terms of [P component weight]/[Ni component weight]×100 (wt %).

An average thickness of the bottom-electrode-forming layer is preferable to be 1 μm to 100 μm. When the average thickness is less than 1 μm, the bottom-electrode-forming layer lose handlability as the capacitor-forming material and lacks reliability as the electrode when the capacitor is formed, and the oxides dielectric layer having uniform film-thickness is made extremely hard to be formed on the surface. On the other hand, the average thickness exceeding 100 μm may never be required. When the metal foil is used and the average thickness of the bottom-electrode-forming layer is made to be 10 μm or less, handling ability of the metal foil might be made difficult. Then, it is preferable to use a metal foil with a carrier foil in which the metal foil and the carrier foil are laminated by the bonding layer, as the metal foil constituting the capacitor-forming material. The carrier foil may be released in an arbitrary stage after the metal foil provided with the carrier foil has been processed to be the capacitor-forming material according to the present invention.

Furthermore, it is preferable to employ a basic composition of (Ba₁₋ₓSrₓ)TiO₃ (0≦x≦1) for the oxides dielectric layer constituting the capacitor-forming material for use in manufacturing of the printed wiring board according to the present invention. This is because that the basic composition can show the most stable adhesion between each of the electrode-forming layers and the oxides dielectric layer in the layer construction which is employed as the capacitor-forming material for use in manufacturing of the printed wiring board according to the present invention. The reason why the composition is referred to as the basic composition is that there is a case in which the composition contains an additive component such as manganese and silicon which will be described below. In the film of (Ba₁₋ₓSrₓ)TiO₃ (0≦x≦1), the case x=0 corresponds to the composition of BaTiO₃ and the case x=1 corresponds to the composition of SrTiO₃. In addition, as for intermediate compositions, (Ba_{0.7}Sr_{0.3})TiO₃ and the like may exist. In addition, it shall be clearly stated for confirmation while taking (Ba₁₋ₓSrₓ)TiO₃ (0≦x≦1) as an example that a ratio between the site A elements (Ba and Sr) and the site B element (Ti) and composition of the oxygen (O) may vary in a certain range in a stoichiometric composition described here.

However, as for a method for forming the oxides dielectric layer, it is not limited as long as the dielectric layer having the basic composition of (Ba₁₋ₓSrₓ)TiO₃ (0≦x≦1) can be prepared. So, various manufacturing methods of the dielectric layer can be employed as the method for forming the oxides dielectric layer. For example, a sol-gel process, an electrophoretic electrodeposition method, a chemical vapor-deposition method such as CVD, a vapor deposition method, a sputtering method and the like can be employed.

The oxides dielectric layer is preferable to contain 0.01 mol % to 5.00 mol % in sum of one or more elements selected from manganese, silicon, nickel, aluminum, lantern, niobium, magnesium and tin. These additive components exist mainly in a state of being segregated in the boundary of crystal grains which constitute the oxides dielectric layer and function blocking the flow channel of a leakage current. So, they are employed from the viewpoint of securing stability as the dielectric layer in a long-term service. These components may be used in alone or in combination, but the content in the oxides dielectric layer is preferable to be 0.01 mol % to 5.00 mol %. When the content of the additive components is less than 0.01 mol %, the additive components are hardly segregated in the grain boundary of the oxides dielectric layer which has been obtained with the sol-gel process, not to show an adequate effect of reducing the leakage current. On the other hand, when the content of the additive components exceed 5.00 mol %, the additive components may excessively segregate in the grain boundary of the oxides dielectric layer obtained with the sol-gel process. Then, the oxides dielectric layer is made brittle to lose toughness and result drawbacks that the dielectric layer is broken due to a shower of an etchant to make the shape of the top electrode or the like by an etching method or the like. The content of the additive components in the oxides dielectric layer is more preferable to be 0.25 mol % to 1.50 mol %. This is because the effect of the oxides dielectric layer for blocking the leakage current is more stabilized. The oxides dielectric layer described above is an oxides dielectric layer having a perovskite structure, and the oxides dielectric layer does not contain the oxide of the above described additive component in principle.

In the capacitor-forming material for use in manufacturing of the printed wiring board according to the present invention, the above described oxides dielectric layer is preferable to have an average thickness of 20 nm to 2 μm, and further preferable to have the average thickness of 20 nm to 1 μm. Because thinner is the average thickness of the oxides dielectric layer, bigger is the capacitance, so, the thinner average thickness is more preferable for the oxides dielectric layer. However, when the oxides dielectric layer has the average thickness of less than 20 nm, the uniformity of the film-thickness of the formed oxides dielectric layer is not assured. So, a dielectric breakdown tends to occur in an early stage and the durability cannot be achieved in a capacitor. In consideration of a required level for the capacitance and the like for the capacitor which is actually required to a market, the average thickness of approximately 2 μm is considered to be a practical upper limit.

Embodiment of Type-Ib: The construction will be described below with reference to FIG. 2. The top-electrode-forming layer 2 of the capacitor-forming material 1 for use in manufacturing of the printed wiring board according to the present invention has a structure constituted with the bulk-metal layer 5, the different-kind-metal layer 7 and the composite layer 6 composed of metal and metal oxide in a stacked manner. As well, the composite layer 6 composed of metal and metal oxide is made to contact with the oxides dielectric layer 4. The adhesion is further enhanced by providing the different-kind-metal layer 7.

In the embodiment of the Type-Ib, as a concept of the bulk-metal layer 5 and the composite layer 6 composed of metal and metal oxide which constitutes the top-electrode-forming layer 2, the oxides dielectric layer 4 and the bottom-electrode-forming layer 3 is the same as that of Type-Ia, so the description will be omitted. Then, just the different-kind-metal layer 7 provided between the bulk-metal layer 5 and the composite layer 6 composed of metal and metal oxide which constitute the top-electrode-forming layer 2 will be described below.

The different-kind-metal layer 7 is preferable to be composed of any one of copper, nickel, the copper alloy and the nickel alloy. The reason why the layer is referred to as “different-kind-metal layer” is that the different-kind-metal layer 7 is composed of a metal component different from that of the above described bulk-metal layer. For example, when nickel is used as the component of the different-kind-metal layer, copper or the like is used as the component of the bulk-metal layer. This is because it secures adequate capacitor-forming capability and enables well balanced design among the strength, the heat spreading performance and the electrical conductivity required for the capacitor is made enable by arranging the layer construction according to the application. The different-kind-metal layer functions as a barrier layer which prevents the oxidation of the composite layer composed of metal and metal oxide in some case. For example, when the composite layer composed of metal and metal oxide is formed in the chamber of a vapor deposition apparatus and then the target material is required to be replaced, the composite layer composed of metal and metal oxide is exposed to the atmosphere once. In such a case, the composition ratio of the composite layer composed of metal and metal oxide may change. However, the change can be prevented when the different-kind-metal layer is provided on the surface of the composite layer composed of metal and metal oxide.

The metal component constituting the different-kind-metal layer is a metal component basically different from that of the bulk-metal layer as described above. However, the same metal component as the metal component constituting the composite layer composed of metal and metal oxide is also applicable. So, specifically, nickel can be used for the different-kind-metal layer when the composite layer of nickel and nickel oxide is used for the composite layer composed of metal and metal oxide.

In such a structure, the different-kind-metal layer is made to perform superior adhesion to both the bulk metal and the composite layer composed of metal and metal oxide. In addition, when a nickel-based material is used as the different-kind-metal layer, heat resistance is made excellent, and when a copper-based material is used as the different-kind-metal layer, heat spreading is made excellent. The copper alloy includes the copper-phosphorus alloy, the copper-zinc alloy, the copper-nickel-zinc alloy, the copper-palladium alloy, the copper-gold alloy and the copper-silver alloy. The nickel alloy includes the nickel-phosphorus alloy, the nickel-cobalt alloy, the nickel-copper alloy, the nickel-palladium alloy, the nickel-silver alloy and the nickel-cobalt-palladium alloy.

When the different-kind-metal layer 7 is provided, moisture absorption resistance, chemical resistance and heat resistance in an etching process for formation of the capacitor circuit is made excellent not to make the adhesion between the oxides dielectric layer and the top-electrode-forming layer in the capacitor poor. In addition, when the capacitor-forming material is finished to be a capacitor in the printed wiring board, the adhesion between the oxides dielectric layer and the top-electrode-forming layer is hardly made poor, and the capacitor can be stably used for a long period of time. When an average thickness of the different-kind-metal layer 7 is less than 30 nm, the effect to stabilize the adhesion between the oxides dielectric layer and the top-electrode-forming layer cannot be promoted. So, it is not preferable. On the other hand, when average thickness of the different-kind-metal layer 7 exceeds 600 nm, the effect to stabilize the adhesion between the oxides dielectric layer and the top-electrode-forming layer is not further enhanced. So, it causes just a waste of resources. So, average thickness of the different-kind-metal layer 7 is preferable to be 30 nm to 600 nm.

As for the manufacturing method of different-kind-metal layer 7, it is preferable to employ a wet manufacturing method of an electro-deposition method or an electroless-deposition method or a physical vapor deposition method of a sputtering method and an EB vapor deposition method which are referred to as a dry process.

Method for manufacturing the capacitor-forming material: As for the method for manufacturing the capacitor-forming material, any manufacturing method can be applicable as long as the layer construction of the capacitor-forming materials of Type-I to Type-III according to the present invention can be obtained.

The manufacturing method of the capacitor-forming material Type-I includes the steps of: “forming of an oxides dielectric layer on a surface of a bottom-electrode-forming layer”; “forming of a top-electrode-forming layer as a stacked body of a two-layer construction constituting [bulk-metal layer]/[composite layer composed of metal and metal oxide], or a three-layer construction constituting [bulk-metal layer]/[different-kind-metal layer]/[composite layer composed of metal and metal oxide], formed on the surface of the oxides dielectric layer”; and “annealing of the stacked body” when required.

The manufacturing method of the capacitor-forming material Type-II includes the steps of: “forming of a bottom-electrode-forming layer having a two-layer construction constituted with a composite layer composed of metal and metal oxide provided on a surface of the bulk-metal layer or having a three-layer construction constituting [different-kind-metal layer]/[composite layer composed of metal and metal oxide] provided on a surface of the bulk-metal layer”; “forming of an oxides dielectric layer on a composite layer composed of metal and metal oxide provided on the surface of the bulk-metal layer of the bottom-electrode-forming layer”; “forming of the top-electrode-forming layer on the surface of the oxides dielectric layer as a stacked body”; and “annealing of the stacked body” when required.

The manufacturing method of capacitor-forming material Type-III includes the steps of: “forming of a bottom-electrode-forming layer having a two-layer construction constituted with a composite layer composed of metal and metal oxide provided on a surface of a bulk-metal layer, or having a three-layer construction constituting [different-kind-metal layer]/[composite layer composed of metal and metal oxide] provided on the surface of the bulk-metal layer”; “forming of an oxides dielectric layer on the composite layer composed of metal and metal oxide provided on the surface of the bulk-metal layer of the bottom-electrode-forming layer”; “forming of a top-electrode-forming layer having a two-layer construction constituting [bulk-metal layer]/[composite layer composed of metal and metal oxide], or having a three-layer construction constituting [bulk-metal layer]/[different-kind-metal layer]/[composite layer composed of metal and metal oxide], on the surface of the oxides dielectric layer as a stacked body”; and “annealing of the stacked body” when required.

Then, the manufacturing method will be described below in more detail by representing Type-Ia illustrated in FIG. 1 and Type-Ib illustrated in FIG. 2. However, it is clearly stated that the concept described can also be applied to manufacturing methods of Type-II and Type-III.

For example, a basic process including steps 1 to 6 can be employed to manufacture the capacitor-forming material. In the process, when the step 5 is omitted, the method is employed for manufacturing the capacitor-forming material having “construction of Type-Ia”, and is referred to as “manufacturing method of Type-Ia”. The method for manufacturing the capacitor-forming material having “construction of Type-Ib” includes all steps 1 to 6, and is referred to as “manufacturing method of Type-Ib”. Each step will be described below, and “manufacturing method of Type-Ia” and “manufacturing method of Type-Ib” will be described together.

Step 1: Step 1 is a solution preparation step in which a sol-gel solution used for manufacturing the oxides dielectric layer having a basic composition of (Ba₁₋ₓSrₓ)TiO₃ (0≦x≦1) is prepared. No particular limitation lies in the step as long as the solution prepared by using a commercially available agent or blended at site it enables to obtain (Ba₁₋ₓSrₓ)TiO₃ (0≦x≦1) film consequently.

Step 2: Step 2 is a coating step in which the film thickness of the layer is adjusted by repeating the unit process several times where the unit process comprises applying of the sol-gel solution on the surface of the bottom-electrode-forming layer (a metal foil having any composition of copper, nickel, the copper alloy and the nickel alloy having the average thickness of 1 μm to 100 μm); drying of the applied sol-gel solution in the oxygen gas-containing atmosphere at 120° C. to 250° C. for 30 seconds to 10 minutes followed by pyrolyzing in the oxygen gas-containing atmosphere at 270° C. to 430° C. for 5 minutes to 30 minutes.

In addition, when the unit process composed of applying of the sol-gel solution on the surface of the bottom-electrode-forming layer (a metal foil having any composition of copper, nickel, the copper alloy and the nickel alloy having the average thickness of 1 μm to 100 μm) and drying of the applied sol-gel solution in the oxygen gas-containing atmosphere at 120° C. to 250° C. for 30 seconds to 10 minutes followed by pyrolyzing in the oxygen gas-containing atmosphere at 270° C. to 430° C. for 5 minutes to 30 minutes is repeated for several times, it is also preferable to provide at least one or more preliminary baking treatments in an inert gas replaced atmosphere or a vacuum at 550° C. to 900° C. for 2 minutes to 60 minutes between one unit process and another one unit process for adjusting the film-thickness. The step is characterized in employing a pyrolysis temperature in such a low temperature region as 270° C. to 430° C. to prevent the further oxidization of the bottom-electrode-forming layer. For example, when one unit process is repeated 6 times and the preliminary baking treatment is carried out once, the process including one unit process (first time)→preliminary baking treatment→one unit process (second time)→one unit process (third time)→one unit process (fourth time)→one unit process (fifth time)→one unit process (sixth time) may be employed. When such a coating step is employed, the obtained oxides dielectric layer is made to comprise structure of fine and high film density and containing few structural defects in the crystal grains. So, the capacitor-forming material finished in the coating step is a dielectric layer into which the etchant is hard to penetrate even when the top electrode circuit is formed by a wet etching method to provide a capacitor of which the leakage current is small and the dielectric layer having high capacitance.

Step 3: Step 3 is the baking step in which the oxides dielectric layer is baked at 550° C. to 900° C. for 5 minutes to 60 minutes as a final baking to finish the oxides dielectric layer having an average thickness of 20 nm to 1 μm on the surface of the bottom-electrode-forming layer. The baking step is a so-called full baking step, and the final oxides dielectric layer is finished through the baking step. In the baking step, the oxides dielectric layer is preferable to be heated in the inert gas replaced atmosphere or the vacuum so as to prevent degradation of the bottom-electrode-forming layer by oxidization. A condition for heating of 550° C. to 850° C. for 5 minutes to 60 minutes is employed. A poor heating less than the temperature condition may make the oxides dielectric layer be hardly baked sufficiently not enable to obtain an oxides dielectric layer excellent in adhesion with the bottom-electrode-forming layer and having a crystal structure of proper density and an appropriate grain size. In addition, with an excess heating exceeding the temperature condition, the degradation in both the oxides dielectric layer and the physical strength of the bottom-electrode-forming layer may progress to hardly achieve superior capacitance and extended life in the finished capacitor.

Step 4: Step 4 is the step for forming a composite layer composed of metal and metal oxide in which the composite layer composed of metal and metal oxide containing any one of copper oxide, nickel oxide, a copper alloy oxide and a nickel alloy oxide having an average thickness of 5 nm to 200 nm is formed by a physical vapor deposition method on the surface of the oxides dielectric layer which has been formed in the baking step. A sputtering method is preferable to be used for the formation of the composite layer composed of metal and metal oxide. This is because the sputtering method can easily form a thin and uniform film, and can easily adjust the ratio of the metal to the metal oxide by arranging the composition of a sputtering target and sputtering conditions (the adjustment of a partial pressure of oxygen gas in a sputtering atmosphere, for example).

Step 5: Step 5 is the step for forming the different-kind-metal layer. The step described is a step used only in a manufacturing method of Type-Ib. In the step, the different-kind-metal layer of any of copper, nickel, the copper alloy and the nickel alloy having an average thickness of 30 nm to 600 nm is formed by a physical vapor deposition method on the surface of the composite layer composed of metal and metal oxide. A sputtering method is preferable to be used for the formation of the different-kind-metal layer. This is because the sputtering method can easily form a thin and uniform film.

Step 6: Step 6 is the bulk-metal layer forming step in which the bulk-metal layer, any one of copper, nickel, the copper alloy and the nickel alloy having an average thickness of 1 μm to 100 μm constituting the top-electrode-forming layer is provided on the surface of the composite layer composed of metal and metal oxide in the case of a manufacturing method of Type-Ia, and on the surface of the different-kind-metal layer in the case of a manufacturing method of Type-Ib. In the case of the manufacturing method of Type-Ib, a metal component different from the different-kind-metal layer is used for a bulk-metal layer. The sputtering method is preferable to be used for the formation of the bulk-metal layer as well. This is because the film thickness control is made easy and good adhesion with the composite layer composed of metal and metal oxide or the different-kind-metal layer formed by the sputtering method can be achieved.

The capacitor-forming material according to the present invention manufactured by the method is preferable to be used as a material after subjecting to annealing treatment at a temperature of 300° C. to 500° C. for 15 minutes to 100 minutes. Subjecting to the annealing treatment enables to achieve effects that reducing of the leakage current and stabilizing of the adhesion to both the dielectric layer and the top-electrode-forming layer in the capacitor formed by using the capacitor-forming material. When the temperature of the annealing treatment is managed at 300° C. to 500° C., the effect for stabilizing the adhesion can be stably achieved in a term of an industrially applicable annealing period of time without increasing the dielectric loss (tan δ). In addition, an inert gas atmosphere is preferable to be used in the annealing treatment.

Then, the leakage currents investigated in the cases with and without carrying out the annealing treatment on the capacitor-forming material which is provided with the top-electrode-forming layer ([bulk-metal layer]/[different-kind-metal layer]/[composite layer composed of metal and metal oxide])/oxides dielectric layer/bottom-electrode-forming layer, and corresponds to Example 1 that will be described later summarized in Table 2. The method for forming a capacitor circuit is same as in Example 1 described later. As for the annealing time, 350° C. for 90 minutes was employed. In addition, the leakage current was measured by using a digital electrometer made by Advantest Corporation.

TABLE 2

| Annealing treatment | Leakage current | Adhesion |
|---|---|---|
| on capacitor-forming | measured | evaluation* |
| material | A/cm² | kgf/cm |
| With annealing | 3.4 × 10⁻⁶ | 0.54-0.58 |
| treatment | | |
| Without annealing | 2.9 × 10⁻³ | 0.16-0.84 |
| treatment | | |

*In the adhesion measurement, 8 points in the same specimen were investigated by using the same evaluation method as in the examples, and the results are shown as a range of the values of the peel strength.

As is obvious in Table 2, the leakage current can be remarkably reduced by subjecting the capacitor-forming material to the annealing treatment. It can be also seen that the deviation of the peel strengths of a sample “with annealing treatment” is clearly smaller than those of a sample of “without annealing treatment”.

[Embodiment of Printed Wiring Board Provided with a Capacitor]

The printed wiring board provided with the capacitor according to the present invention is characterized in being obtained by using the above described capacitor-forming material. In other words, the capacitor-forming material according to the present invention is preferable to be used for the formation of an embedded capacitor layer of a multilayer printed wiring board. The top-electrode-forming layer and the bottom-electrode-forming layer provided on both sides of capacitor-forming material are made to be a capacitor circuit shape by an etching method to finish a material constituting an embedded capacitor layer of the multilayer printed wiring board. The method for manufacturing the multilayer printed wiring board is not limited at all.

Further, the flat capacitor-forming material according to the present invention in an as-received size or an arbitrary size after cutting can be embedded in a printed wiring board. As for the method for cutting the capacitor-forming material into the small pieces, any cutting method may be employed if the top-electrode-forming layer and the bottom-electrode-forming layer which sandwich the oxides dielectric layer never come in contact with each other on the cut edge to result short circuit. As for example in the methods, after the top-electrode-forming layer and the bottom-electrode-forming layer are etched in a lattice shape by an etching method, and then braking method, laser cutting method, a wire saw method and a share cutting method can be carried out on the exposed oxides dielectric layer to obtain small pieces.

The embedded capacitor circuit formed by using the capacitor-layer forming material and the small-sized capacitor peaces embedded in the wiring of the printed wiring board have the superior adhesion between the electrode layer and the oxides dielectric layer because the electrode layer has the stacked layer construction of two layers or three layers.

### Example 1

In the Example 1, the capacitor-forming material was manufactured by forming the oxides dielectric layer on the surface of a nickel foil as a metal substrate (a bottom-electrode-forming layer) followed by forming a composite layer composed of metal and metal oxide on the surface of the oxides dielectric layer and a different-kind-metal layer on the composite layer composed of metal and metal oxide, and a bulk-metal layer is formed thereon to be a top-electrode-forming layer. Then, a capacitor circuit was formed on the capacitor-forming material by an etching method, and the various properties of dielectric material were investigated.

### [Manufacturing of Bottom-Electrode-Forming Layer]

In the example 1, a nickel foil having the average thickness of 50 μm manufactured by a rolling method was used. The average thickness of the nickel foil manufactured by the rolling method above is a gauge thickness. After finishing the capacitor-forming material, the layer composed of nickel foil is used for forming the bottom electrode-forming circuit.

Before forming of the dielectric layer on the surface of the nickel foil, the nickel foil was heated at 250° C. for 15 minutes and was irradiated with a UV light for 1 minute as pretreatment, just before providing the dielectric layer.

### [Manufacturing of Capacitor-Forming Material]

Step 1: In the solution preparation step, a sol-gel solution used in a sol-gel process was prepared. The sol-gel solution to provide the oxides dielectric layer having the composition of Ba_{0.9}Sr_{0.1}TiO₃ was prepared by using a BST-thin-film-forming agent, a trade name “7 wt % BST” made by Mitsubishi Materials Corporation.

Step 2: In the coating step, one unit process was made to be sequential step of: coating of the sol-gel solution on a surface of a metal substrate; drying of the applied sol-gel solution at 150° C. for 2 minutes in oxygen gas-containing atmosphere; and pyrolysis at 390° C. for 15 minutes in oxygen gas-containing atmosphere. The film-thickness was adjusted by repeating the unit process 12 times in which preliminary baking treatments were carried out at 700° C. for 15 minutes in an inert gas replaced atmosphere after the first unit process, the third unit process, the sixth unit process and the ninth unit process each once.

Step 3: In the baking step, the baking treatment as the final step in the inert gas replaced atmosphere (nitrogen-gas replaced atmosphere) at 850° C. for 30 minutes on the oxides dielectric layer provided on the surface of the bottom-electrode-forming layer (nickel foil) after finishing the above described coating step.

Step 4: The baked material was put into a vacuum chamber of a sputtering apparatus in which a nickel target was provided. Then, argon gas and oxygen gas were introduced in the vacuum chamber at flow rates of 72 cc/min and 5.0 cc/min respectively, and the partial pressure of oxygen (gas) was kept at a steady state of 3.7×10⁻⁴ Torr. Next, a composite layer of nickel and nickel oxide (the composite layer composed of metal and metal oxide) having the average thickness of 100 nm and a peak intensity ratio of 0.06 to 5.68 was formed by a sputtering method. The range of peak intensity ratio above is a value obtained in the whole examples, Examples 1 to 3.

Step 5: Introduction of oxygen gas into the vacuum chamber of the sputtering apparatus was stopped and kept to make the chamber free from oxygen gas. After being made free from the oxygen gas, the nickel layer (different-kind-metal layer) having the average thickness of 500 nm was formed on the composite layer composed of metal and metal oxide by carrying out the sputtering again. Thus, a stacked body having a two-layer construction constituting [composite layer composed of nickel and nickel oxide]/[nickel layer] was formed.

Step 6: A copper layer having the average thickness of 2 μm was formed as a bulk-metal layer on the stacked body formed in the above described procedure by sputtering method. A copper target was provided in the vacuum chamber. Thereby, the capacitor-forming material comprising the top-electrode-forming layer having a three-layer construction constituting [composite layer composed of metal and metal oxide]/[different-kind-metal layer]/[bulk-metal layer] was prepared.

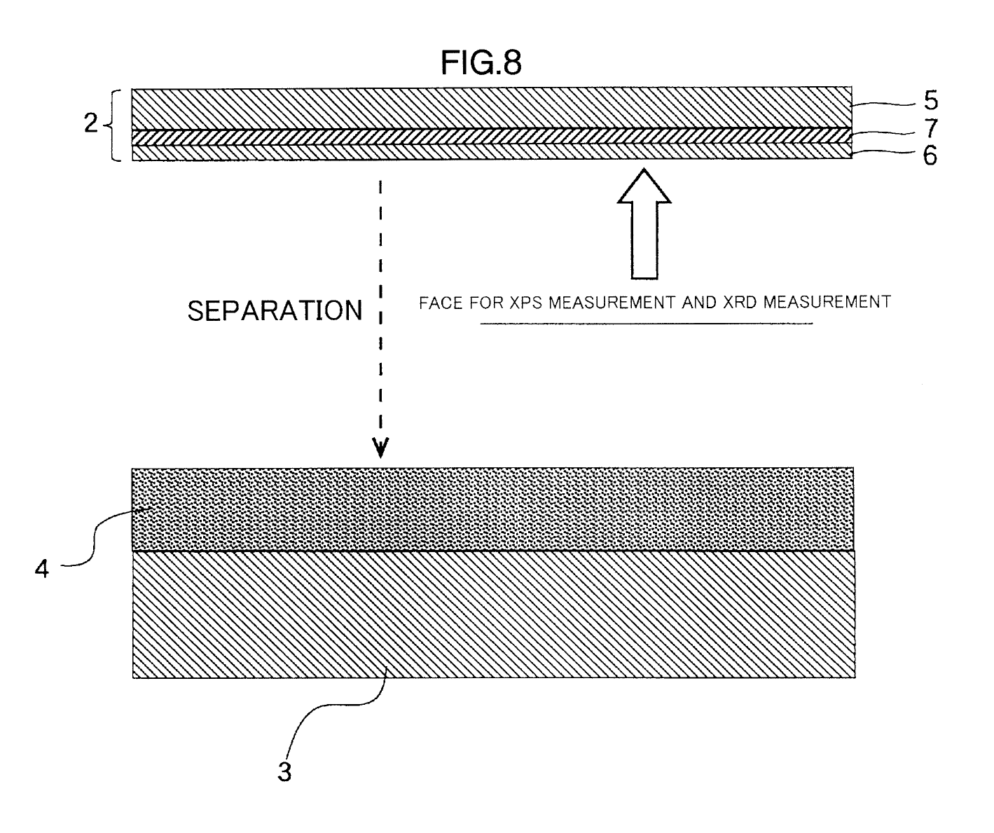

XPS measurement and XRD measurement: As is illustrated in FIG. 8 (a layer construction of Example 1 corresponding to the construction of Type-Ib), an XPS spectrum and an XRD spectrum were investigated on the composite layer 6 composed of metal and metal oxide after peeling off the composite layer 6 composed of metal and metal oxide from the dielectric layer 4 at the interface, and carrying out the XPS measurement and the XRD measurement. QUANTUM 2000 made by ULVAC-PHI, Inc. was used as the XPS measuring apparatus and X′Pert Pro made by PANalytical B.V. was used as the XRD measuring apparatus. All of these measurement results are summarized in Table 3.

### [Formation of Capacitor Circuit]

The top-electrode-forming layer of the capacitor-forming materials were provided with an etching resist layer on the surface followed by exposing the light to obtain an etching pattern to be formed on a top electrode circuit shape, and was subjected to development. After this, the top-electrode-forming layer was etched by an etchant, the etching resist was stripped, and a capacitor circuit which is the top electrodes with the size of 4 mm×4 mm was formed.

### [Evaluation of Dielectric Performance]

Capacitance density: The initial average capacitance density of the capacitor of which the top electrodes with the size of 4 mm×4 mm showed an excellent capacitance of 1,214 nF/cm². For information, the capacitance densities of Examples and Comparative examples which will be described later are an average value measured on 30 electrodes.

Dielectric loss: The dielectric loss in the capacitor circuit having the top electrodes with the size of 4 mm×4 mm were measured, and the dielectric loss was 0.041. For information, the dielectric loss of Examples and Comparative examples which will be described later are an average value measured on three samples.

Leakage current: The leakage current was measured on a capacitor circuit of the top electrodes with the size of 4 mm×4 mm by using a digital electrometer made by Advantest Corporation.

Adhesion: The adhesion was measured as peel strength between the top-electrode-forming layer and the dielectric layer. Specifically, after plating the copper on the top-electrode-forming layer of the capacitor-forming material to be the average thickness of 22 μm, a straight wiring with the width of 30 mm for measuring the peel strength was formed. It shall be clearly stated that the copper plating was carried out for the convenience of the measurement and had no relationship with the constitution of the present invention. As a result, the peel strength was 0.373 kgf/cm. For information, the peel strengths of Examples and Comparative examples which will be described later are the average value measured on three samples. In addition, the peel strength was measured by using autograph (AGS-1kNG) made by Shimadzu Corporation with cross-head speed of 50 mm/min.

Each of the performance described above is summarized in Table 3 to make comparison with those of Examples and Comparative examples which will be described below easy.

### Example 2

In the Example 2, a similar process to that in Example 1 was carried out to prepare a capacitor-forming material. Then, the capacitor-forming material was investigated in the same way. Just the difference in Example 2 from Example 1 made to be was that the average thickness of the composite layer composed of nickel and nickel oxide was made to be 50 nm. Each of the performance of the sample was summarized in Table 3 to make comparison with those of Example 1, Example 3 and Comparative examples which would be described below easy.

### Example 3

In the Example 3, a similar process to that in Example 1 was carried out to prepare a capacitor-forming material and the capacitor-forming material was subjected to annealing treatment and was investigated in the same way. So, just the difference in Example 3 from Example 1 made to be was that the annealing treatment was carried out. The annealing treatment was carried out on the capacitor-forming material prepared in Example 1 in a nitrogen gas stream atmosphere at a temperature of 350° C. for 90 minutes. Each of the performance of the sample was summarized in Table 3 to make comparison with those of Examples 1 to 2 and Comparative examples which would be described below easy.

### COMPARATIVE EXAMPLES

### Comparative Example 1

In the comparative example 1, a step 4 of Example 1 was skipped, and a metal layer (nickel layer) having the average thickness of 600 nm was formed in just the step 5. So, the peak intensity ratio corresponds to infinity (∞). Other steps were carried out in a similar way to those in Examples to finish a capacitor-forming material.

The capacitor-forming material was investigated in a same way to those in Examples. As a result, the average capacitance density was 1,127 nF/cm², the dielectric loss was 0.023, and the peel strength was 0.004 kgf/cm.

Each of the performance described above was summarized in Table 3 to make comparison with those of Examples and other Comparative examples easy.

### Comparative Example 2

In the comparative example 2, a composite layer composed of metal and metal oxide was prepared by making the flow rate of the oxygen gas in the step 4 of Example 1 to be 2.5 cc/min, and the partial pressure of oxygen gas was made to be 1.8×10⁻⁴ Torr. However, as a result of the investigation on the composite layer composed of metal and metal oxide prepared with an X-ray diffraction method, the peak for nickel oxide was extremely small, i.e. formation of the nickel oxide was failed even it was intended to form. It means that the layer might be not a composite layer composed of metal and metal oxide but a nickel. So, in comparison with Examples, Comparative example 2 is treated as same as Comparative example 1. Other steps were carried out in a similar way to Examples to finish a capacitor-forming material.

The capacitor-forming material was investigated in a same way to those in Examples. As a result, the average capacitance density was 1,158 nF/cm², the dielectric loss was 0.021, and the peel strength was 0.010 kgf/cm.

Each of the performance described above was summarized in Table 3 to make comparison with those of Examples and other Comparative examples easy.

### Comparative Example 3

In the Comparative example 3, the flow rate of the oxygen gas in the step 4 of Example 1 was made to be 10.0 cc/min, and the partial pressure of oxygen gas was 6.8×10⁻⁴ Torr, to form a nickel oxide layer on the oxides dielectric layer, i.e. only the metal oxide layer constituted with just the metal oxide having the average thickness of 100 nm. The metal oxide layer was investigated with an X-ray diffraction method. As a result, nickel not oxidized was hardly observed, and it can be said that only the peak of nickel oxide is detected. So, it was considered to be [Ni (101)]=0, and the peak intensity ratio corresponds to infinitesimal (≈0). Other steps were carried out in a similar way to those in Examples to prepare a capacitor-forming material.

The capacitor-forming material was investigated in a same way to those in Examples. As a result, the average capacitance density was 347 nF/cm², the dielectric loss was 0.143, and the peel strength was 0.263 kgf/cm.

Each of the performance described above was summarized in Table 3 to make comparison with those of Example s and other Comparative examples.

### Comparative Example 4

In the Comparative example 4, the baked material was put into a vacuum chamber of a sputtering apparatus in which a copper target is provided, introducing oxygen gas into the vacuum chamber at a flow rate of 10.0 cc/min, and setting the partial pressure of oxygen gas at a steady state of 6.8×10⁻⁴ Torr in the step 4 in Example 1. Thus, the copper oxide layer having the average thickness of 100 nm was formed by a sputtering method. Then, introduction of the oxygen gas into the vacuum chamber of the sputtering apparatus was stopped and kept to make the chamber completely free from the oxygen gas, a copper layer having the average thickness of 2 μm was formed as a bulk-metal layer on the metal oxide layer by using a sputtering method again. The copper oxide layer was investigated with an X-ray diffraction method. As a result, copper not oxidized was hardly observed, and it can be said that just the peak of copper oxide was detected. So, [Cu (200)] was estimated to be =0, i.e. ([Cu (200)]/[Cu₂O (111)]) of the composite layer of copper and copper oxide (composite layer composed of metal and metal oxide) formed is ≈0 which is the ratio corresponds to the peak intensity ratio of Examples. Other steps were carried out in a similar way to those in Examples to finish a capacitor-forming material. For information, Cu refers to PDF card #04-0836, and Cu₂O refers to PDF card #05-0667.

The capacitor-forming material was investigated in a same way to those in Examples. As a result, the average capacitance density was 947 nF/cm², the dielectric loss was 0.028, and the peel strength was 0.005 kgf/cm.

Each of the performance described above was summarized in Table 3 to enable comparison among Examples and Comparative examples.

TABLE 3

| | Forming | | | | | |
|---|---|---|---|---|---|---|
| | condition for | | | | | |
| | composite | | | | | |
| | layer¹⁾ | | | | Possibility for | |
| | Partial | | | | observation | |
| | pressure of | | | | of separated | Peak |
| | oxygen gas²⁾ | Adhesion³⁾ | Cp⁴⁾ | tanδ⁵⁾ | spectra in | intensity |
| Sample | Torr | kgf/cm | nF/cm2 | — | XPS | ratio⁶⁾ |
| Example 1 | 3.7 × 10⁻⁴ | 0.373 | 1214 | 0.041 | Possible | 0.06-5.68 |
| Example 2 | | 0.314 | 1015 | 0.036 | | |
| Example 3 | | 0.544 | 1442 | 0.045 | | |
| Comparative | — | 0.004 | 1127 | 0.023 | Impossible | ∞ |
| example 1 | | | | | | |
| Comparative | 1.8 × 10−4 | 0.010 | 1158 | 0.021 | | |
| example 2 | | | | | | |
| Comparative | 6.8 × 10⁻⁴ | 0.263 | 347 | 0.143 | | ≈0 |
| example 3 | | | | | | |
| Comparative | | 0.005 | 947 | 0.028 | Unmeasured | |
| example 4 | | | | | | |

¹⁾The forming condition for the composite layer is a condition for forming the composite layer composed of metal and metal oxide, but in Comparative examples, the layer does not become a composite layer composed of a metal and a metal oxide.
²⁾The partial pressure of oxygen gas, at which a steady state in the sputtering apparatus was kept when oxygen gas was passed thereinto and the composite layer composed of metal and metal oxide was formed by the sputtering method.
³⁾A value which is a peel strength that expresses adhesion.
⁴⁾It corresponds to the average capacitance density.
⁵⁾It corresponds to the dielectric loss.
⁶⁾The peak intensity ratio is a value obtained by calculating [Ni(101)]/[NiO(200)] in an XRD analysis, but is value of [Cu(200)]/[Cu₂O(111)] in Comparative Example 4.

### Comparison Among Examples and Comparative Examples

As is clear in Table 3 on Comparative example 1 and Comparative example 2, when the composite layer composed of metal and metal oxide is not the composite layer but metal nickel, the average capacitance density (Cp) is large, and a dielectric loss (tan δ) is small, i.e. it looks to have adequate capacitor performance. However, in Comparative example 1 and Comparative example 2, the values of the peel strength (adhesion) between the top-electrode-forming layer and the dielectric layer are extremely low. So, the Comparative examples may make a risk after the capacitor-forming material has been processed into the capacitor circuit big that the peeling of the top electrode-forming circuit due to vibration, the peeling of the top electrode-forming circuit due to a shock in handling, the peeling of the top electrode-forming circuit due to an expansion behavior of a printed wiring board caused by a heat generation in operation and the like of the printed wiring board.

Next, Comparative example 3 will be examined. As is clear in Table 3 on Comparative example 3, even when just a nickel oxide layer is provided in place of the composite layer composed of metal and metal oxide, the peel strength (adhesion) between the top-electrode-forming layer and the dielectric layer does not achieve a practical value (0.3 kgf/cm or more). Besides, the average capacitance density (Cp) is extremely low, and the dielectric loss (tan δ) also shows a large value. So, it can be said that Comparative example 3 does not satisfy basic performance required on a capacitor circuit.

Furthermore, Comparative example 4 will be examined. As is clear in Table 3 on Comparative example 4, when just a copper oxide layer is provided in place of the composite layer composed of metal and metal oxide, the peel strength (adhesion) between the top-electrode-forming layer and the dielectric layer is made extremely low. Besides, the capacitance density of the capacitor circuit is made low.

When Examples are examined in comparison with each of the Comparative examples, the average capacitance density (Cp) is larger, the dielectric loss (tan δ) is also comparatively lower, and the values of the peel strength (adhesion) between the top-electrode-forming layer and the dielectric layer is high as 0.314 kgf/cm to 0.544 kgf/cm. In other words, it can be said that the capacitor-forming material according to the present invention is superior in a total balance. In addition, the printed wiring board provided with the capacitor circuit obtained by using the capacitor-forming material is made to have capacitor performance of high quality and is made superior in stability for a long-term use.

Then, the peak intensity ratio among Examples and Comparative examples will be compared. The capacitor-forming materials provided in Comparative examples have no condition of the peak intensity ratio, which the capacitor-forming material according to the present invention should have. In other words, it can be an index for having an adequate adhesion between the top-electrode-forming layer and the oxides dielectric layer of the capacitor-forming material according to the present invention to satisfy the peak intensity ratio.

### INDUSTRIAL APPLICABILITY

The capacitor-forming material according to the present invention is characterized in provided with either of layer constructions of a composite layer composed of metal and metal oxide or [composite layer composed of metal and metal oxide]/[different-kind-metal layer], between an oxides dielectric layer and a bulk-metal layer constituting an electrode-forming layer. By having such a layer construction, the adhesion between the electrode-forming layer and the oxides dielectric layer is made excellent. So, when the printed wiring board provided with an embedded capacitor is manufactured by using a capacitor-forming material for use in manufacturing of a printed wiring board according to the present invention, the printed wiring board is made to comprise capacitor performance of high quality, and can be supplied to a market as a durable product.

As can be understood from the layer construction of the capacitor-forming material according to the present invention described above, the capacitor-forming material can be manufactured by using an existing facility without an additional special apparatus, and does not require a large investment in plant and equipment. The capacitor-forming material shows an adequate adhesion between the oxides dielectric layer and the top-electrode-forming layer, and provides a product of high quality in a state of securing a high capacitance.

### DESCRIPTION OF SYMBOLS

1a capacitor-forming material (Type-Ia)
1b capacitor-forming material (Type-Ib)
10a capacitor-forming material (Type-IIa)
10b capacitor-forming material (Type-IIb)
20a capacitor-forming material (Type-IIIa)
20b capacitor-forming material (Type-IIIb)
2 top-electrode-forming layer
3 bottom-electrode-forming layer
4 oxides dielectric layer
5 bulk-metal layer
6 composite layer composed of metal and metal oxide
7 different-kind-metal layer

1. A capacitor-forming material provided with an oxides dielectric layer between a top-electrode-forming layer and a bottom-electrode-forming layer, wherein
at least one of the top-electrode-forming layer and the bottom-electrode-forming layer has a two-layer construction constituted with a bulk-metal layer and a composite layer composed of metal and metal oxide which is made to contact with the oxides dielectric layer.

2. The capacitor-forming material according to claim 1, wherein
the top-electrode-forming layer has the two-layer construction constituted with the bulk-metal layer and the composite layer composed of metal and metal oxide, and has a layer construction in which the bulk-metal layer and the composite layer composed of metal and metal oxide are stacked to make the composite layer composed of metal and metal oxide contact with the oxides dielectric layer.

3. The capacitor-forming material according to claim 1, wherein when the composite layer composed of metal and metal oxide is investigated with an X-ray photoelectron spectroscopic analysis, spectrums of the metal and metal oxide constituting the composite layer composed of metal and metal oxide can be distinguished in a separated state from each other.

4. The capacitor-forming material according to claim 1, wherein the metal oxide constituting the composite layer composed of metal and metal oxide is any one of copper oxide, nickel oxide, a copper alloy oxide and a nickel alloy oxide.

5. The capacitor-forming material according to claim 1, wherein
when the composite layer composed of metal and metal oxide is a composite of nickel and nickel oxide, a peak intensity ratio ([Ni (101)]/[NiO (200)]) calculated from the peak intensity (Ni (101)) of the (101) face of nickel to the peak intensity (NiO (200)) of the (200) face of nickel oxide obtained in measuring X-ray diffraction of the composite is in a range of 0.02 to 50.

6. The capacitor-forming material according to claim 1, wherein
the composite layer composed of metal and metal oxide has an average thickness of 5 nm to 200 nm.

7. The capacitor-forming material according to claim 1, wherein
the bulk-metal layer constituting the top-electrode-forming layer and the bottom-electrode-forming layer is constituted with any of copper, nickel, a copper alloy and a nickel alloy.

8. The capacitor-forming material according to claim 1, wherein
at least one of the top-electrode-forming layer and the bottom-electrode-forming layer has a three-layer construction in which a different-kind-metal layer is provided between the bulk-metal layer and the composite layer composed of metal and metal oxide.

9. The capacitor-forming material according to claim 8, wherein
the different-kind-metal layer has a metal component different from that of the bulk-metal layer, and is constituted with a metal component contained in the composite layer composed of metal and metal oxide.

10. The capacitor-forming material according to claim 8, wherein
the different-kind-metal layer has an average thickness of 30 nm to 600 nm.

11. The capacitor-forming material according to claim 1, wherein
the oxides dielectric layer has a basic composition of (Ba₁₋ₓSrₓ)TiO₃ (wherein 0≦x≦1).

12. The capacitor-forming material according to claim 1, wherein
the oxides dielectric layer has an average thickness of 20 nm to 2 μm.

13. A method for manufacturing the capacitor-forming material according to claim 1 characterized in that the stacked body is manufactured through:
the oxides dielectric layer is formed on a surface of the bottom-electrode-forming layer; and then
the top-electrode-forming layer having a two-layer construction constituting [bulk-metal layer]/[composite layer composed of metal and metal oxide], or the top-electrode-forming layer having a three-layer construction constituting [bulk-metal layer]/[different-kind-metal layer]/[composite layer composed of metal and metal oxide] is formed on the surface of the oxides dielectric layer.

14. The method for manufacturing the capacitor-forming material according to claim 13, wherein
the stacked body is subjected to annealing treatment.

15. A method for manufacturing the capacitor-forming material according to claim 1 characterized in that the stacked body is manufactured through:
the bottom-electrode-forming layer having two-layer construction is formed by providing a composite layer composed of metal and metal oxide on a surface of a bulk-metal layer, or the bottom-electrode-forming layer having three-layer construction is formed by providing a different-kind-metal layer on a surface of a bulk-metal layer followed by providing a composite layer composed of metal and metal oxide on a surface of a different-kind-metal layer;
then the oxides dielectric layer is formed on the composite layer composed of metal and metal oxide provided on the surface of the bottom-electrode-forming layer; and
further the top-electrode-forming layer is formed on the surface of the oxides dielectric layer.

16. The method for manufacturing the capacitor-forming material according to claim 15, wherein
the stacked body is subjected to annealing treatment.

17. A method for manufacturing the capacitor-forming material according to claim 1 characterized in that the stacked body is manufactured through:
the bottom-electrode-forming layer is formed by providing a two-layer construction formed by providing the composite layer composed of metal and metal oxide on a surface of the bulk-metal layer, or providing a three-layer construction constituting [different-kind-metal layer]/[composite layer composed of metal and metal oxide] on a surface of the bulk-metal layer;
then the oxides dielectric layer is formed on the composite layer composed of metal and metal oxide provided on the surface of the bottom-electrode-forming layer; and
forming the top-electrode-forming layer having a two-layer construction constituting [bulk-metal layer]/[composite layer composed of metal and metal oxide], or the top-electrode-forming layer having a three-layer construction constituting [bulk-metal layer]/[different-kind-metal layer]/[composite layer composed of metal and metal oxide] on the surface of the oxides dielectric layer.

18. The method for manufacturing the capacitor-forming material according to claim 17, wherein
the stacked body is subjected to annealing treatment.

19. A printed wiring board characterized in that the printed wiring board is obtained by forming an embedded capacitor layer by using the capacitor-forming material according to claim 1.

20. A printed wiring board characterized in that the printed wiring board is obtained by providing the capacitor-forming material according to claim 1 in a printed wiring board.
